(19) United States
(12) Patent Application Publication
(10) Pub. No.: US 2025/0261497 A1
(43) Pub. Date: Aug. 14, 2025

(54) DISPLAY PANEL AND DISPLAY DEVICE

(71) Applicants: Yunnan Invensight Optoelectronics Technology Co., Ltd., Yunnan (CN); BOE Technology Group Co., Ltd., Beijing (CN)

(72) Inventors: Chao PU, Beijing (CN); Xiaochuan CHEN, Beijing (CN); Yinhu HUANG, Beijing (CN); Shengji YANG, Beijing (CN); Pengcheng LU, Beijing (CN); Hao XU, Beijing (CN); Zhao MA, Beijing (CN); Mingrui ZHANG, Beijing (CN); Liuzeming QU, Beijing (CN); Qi SU, Beijing (CN); Zhuoyang XIE, Beijing (CN)

(73) Assignees: Yunnan Invensight Optoelectronics Technology Co., Ltd., Yunnan (CN); BOE Technology Group Co., Ltd., Beijing (CN)

(21) Appl. No.: 18/701,352

(22) PCT Filed: Jul. 19, 2023
(86) PCT No.: PCT/CN2023/108222

§ 371 Date: Apr. 15, 2024

(30) Foreign Application Priority Data
May 25, 2023 (CN) 202310602230.4

(51) Int. Cl. H10H 29/855; H10H 29/37; H10H 29/80; H10H 29/85; H10H 29/853

(52) U.S. Cl. CPC H10H 29/8552; H10H 29/37; H10H 29/8321; H10H 29/8517; H10H 29/853

(57) ABSTRACT

Disclosed are a display panel and a display device. The display panel is provided with an display region and a peripheral region, and includes a display substrate and at least one alignment mark disposed in the peripheral region. The display substrate is sequentially provided with a first packaging layer, a light-shielding layer, and a second packaging layer at a side, distal to the base substrate, of a second electrode layer. The light-shielding layer is provided with an opening hole, and a distance between a medial edge of the opening hole and a first end of the light-shielding layer is greater than a distance between a lateral edge of the opening hole and a second end of the light-shielding layer.

This application claims priority to Chinese Patent Application No. 202310602230.4, filed on May 25, 2023 and entitled “DISPLAY PANEL AND DISPLAY DEVICE”, the content of which is herein incorporated by reference in its entirety.

### TECHNICAL FIELD

The present disclosure relates to the field of display technologies, and in particular, to a display panel and a display device.

### BACKGROUND

A display panel includes a display substrate and a cover plate attached to the upper surface of the display substrate. For ensuring the accuracy of attachment of the cover plate, an alignment mark is typically provided in a peripheral region of the display substrate, and the cover plate is therefore aligned with the display substrate based on the alignment mark. The alignment mark is typically made of a metal of the anode layer, and an external light is incident onto the surface of the metal of the anode layer and reflected off to form an alignment mark pattern.

### SUMMARY

A first aspect of the present disclosure provides a display panel. The display panel is provided with a display region and a peripheral region disposed around the display region, the display panel including: a display substrate, including a base substrate, and a first electrode layer, a pixel definition layer, a light-emitting unit, and a second electrode layer sequentially disposed at a side of the base substrate, where the pixel definition layer is provided with an opening region and a non-opening region surrounding the opening region, and the light-emitting unit is disposed in the opening region; and at least one alignment mark disposed in the peripheral region, where the display substrate further includes: a first packaging layer, a light-shielding layer, and a second packaging layer sequentially disposed at a side, distal to the base substrate, of the second electrode layer, where the first packaging layer covers the display region and the peripheral region, the light-shielding layer is disposed in the peripheral region, and the second packaging layer covers the display region and the peripheral region; the light-shielding layer is provided with an opening hole, and the opening hole is disposed opposite to the alignment mark; and a distance between a medial edge of the opening hole and a first end of the light-shielding layer is greater than a distance between a lateral edge of the opening hole and a second end of the light-shielding layer, where the first end is an end, close to the display region, of the light-shielding layer, and the second end is an end, distal to the display region, of the light-shielding layer.

In some embodiments, an orthographic projection of the opening hole on the base substrate falls within a range of an orthographic projection of the alignment mark on the base substrate.

In some embodiments, the display substrate further includes a cathode ring, the alignment mark is spaced apart from the cathode ring, and a spacing distance between the alignment mark and the cathode ring is greater than a width of the cathode ring.

In some embodiments, the display panel further includes a cover plate disposed at a side, distal to the base substrate, of the second packaging layer and connected to the display substrate; and an orthographic projection of an end, distal to the display region, of the cover plate on the light-shielding layer falls a range of the opening hole.

In some embodiments, the alignment mark is disposed on a same layer as the first electrode layer or the second electrode layer.

In some embodiments, a first overlapping region and a second overlapping region are present between an orthographic projection of the light-shielding layer on the base substrate and an orthographic projection of the alignment mark on the base substrate, the first overlapping region is disposed at a side, distal to the display region, of the opening hole, the second overlapping region is disposed at a side, close to the display region, of the opening hole, and a width of the first overlapping region is greater than a width of the second overlapping region.

In some embodiments, the width of the second overlapping region is smaller than the spacing distance between the alignment mark and the cathode ring.

In some embodiments, a longitudinal section of the opening hole has a stepped structure.

In some embodiments, a cross-section of the alignment mark in a direction parallel to a major plane of the base substrate is L-shaped or T-shaped or cross-shaped.

In some embodiments, vertex corners and/or edge corners of the alignment mark contacting the first packaging layer are rounded corners.

In some embodiments, the alignment mark is L-shaped, and a curvature of a medial rounded corner is greater than a curvature of a lateral rounded corner of the alignment mark.

In some embodiments, at least two of the alignment marks are provided, and every two of the alignment marks adjacent to each other are symmetrically distributed relative to a center of the display panel.

In some embodiments, the display panel is rectangular, diamond-shaped, or square, and the alignment marks are opposite respectively to positions of vertex corners of the display panel; or the display panel is circular.

In some embodiments, the display panel is rectangular, diamond-shaped, or square, and four of the alignment marks are provided opposite respectively to positions of four vertex corners of the display panel.

In some embodiments, edge corners and vertex corners of the light-shielding layer at sides, close to the base substrate and/or distal to the base substrate, of the opening hole are rounded corners.

In some embodiments, the light-shielding layer includes a first peripheral color resistance layer and a second peripheral color resistance layer sequentially disposed at a side, distal to the base substrate, of the first packaging layer, where the first peripheral color resistance layer and the second peripheral color resistance layer are each one of a red color resistance layer, a green color resistance layer, and a blue color resistance layer.

In some embodiments, the light-shielding layer further includes a third peripheral color resistance layer disposed at a side, distal to the base substrate, of the second peripheral color resistance layer, where the first peripheral color resistance layer, the second peripheral color resistance layer, and the third peripheral color resistance layer are each one of the red color resistance layer, the green color resistance layer, and the blue color resistance layer.

In some embodiments, the light-shielding layer is a black color resistance layer.

In some embodiments, the display region is provided with a first display region color resistance layer, a second display region color resistance layer, and a third display region color resistance layer arranged in an array at the side, distal to the base substrate, of the first packaging layer, where the first display region color resistance layer, the second display region color resistance layer, and the third display region color resistance layer are each one of the red color resistance layer, the green color resistance layer, and the blue color resistance layer; and each of the peripheral color resistance layers in the light-shielding layer is manufactured synchronously with one of the first display region color resistance layer, the second display region color resistance layer, and the third display region color resistance layer in the display region.

In some embodiments, the display panel further includes a rubber frame, and a surface at a side, distal to the base substrate, of the rubber frame is higher than a surface at a side, distal to the base substrate, of the cover plate.

A second aspect of the present disclosure provides a display device. The display device includes a power supply assembly and the display panel as defined above, where the power supply assembly is configured to supply power to the display panel.

### BRIEF DESCRIPTION OF THE DRAWINGS

For clearer illustration of the technical solutions in the embodiments of the present disclosure or in the prior art, the accompanying drawings required to be used in the description of the embodiments or the prior art are briefly introduced below. It is apparent that the accompanying drawings in the description below are only for some embodiments of the present disclosure, and for those of ordinary skill in the art, other embodiments can be acquired according to the accompanying drawings.

FIG. 1 is a simplified schematic structural view of a display panel according to some embodiments of the present disclosure in a top view;

FIG. 2 is a sectional view of a peripheral region of a display panel according to some embodiments of the present disclosure in one embodiment;

FIG. 3 is a sectional view of a peripheral region of a display panel according to some embodiments of the present disclosure in another embodiment;

FIG. 4 is a schematic structural view of the attachment between a cover plate and a display substrate of a display panel according to some embodiments of the present disclosure;

FIG. 5 is a schematic top view of a display panel according to some embodiments of the present disclosure in one embodiment;

FIG. 6 is an enlarged schematic structural view of portion C in FIG. 5;

FIG. 7 is a schematic structural view of an opening hole of a light-shielding layer of a display panel according to some embodiments of the present disclosure in one embodiment;

FIG. 8 is a schematic structural view of an opening hole of a light-shielding layer of a display panel according to some embodiments of the present disclosure in a second embodiment;

FIG. 9 is a schematic structural view of an opening hole of a light-shielding layer of a display panel according to some embodiments of the present disclosure in a third embodiment;

FIG. 10 is a schematic structural view of an opening hole of a light-shielding layer of a display panel according to some embodiments of the present disclosure in a fourth embodiment;

FIG. 11 is a schematic structural view of an opening hole of a light-shielding layer of a display panel according to some embodiments of the present disclosure in a fifth embodiment; and

FIG. 12 is a schematic structural view of a display device according to some embodiments of the present disclosure.

Reference numerals are as follows:
display region 10; peripheral region 20; dummy pixel region 21; cathode ring region 22; cathode ring 221; shift pixel region 23; readout region 24;
base substrate 100; first insulating layer 101; first conductive pillar 102; reflective electrode 103; second insulating layer 104; second conductive pillar 105; first electrode layer 106; pixel definition layer 107; opening region 1071; non-opening region 1072; light-emitting unit 108; second electrode layer 109; first packaging layer 110; color film layer 111; first display region color resistance layer 1111; second display region color resistance layer 1112; third display region color resistance layer 1113; light-shielding layer 112; first end 112a; second end 112b; first peripheral color resistance layer 1121; second peripheral color resistance layer 1122; third peripheral color resistance layer 1124; opening hole 1123; medial edge 1123a; lateral edge 1123b; second packaging layer 113; cover plate 114; alignment mark 115; rubber frame 116; double-sided adhesive tape 117; optical adhesive 118; spacing distance S; width of the cathode ring L; first overlapping region A; second overlapping region B;
display panel 1000; power supply assembly 2000.

### DETAILED DESCRIPTION

The technical solutions in the embodiments of the present disclosure will be described clearly and fully with reference to the accompanying drawings in the embodiments of the present disclosure, and it is apparent that the embodiments described are only a part, but not all of the embodiments of the present disclosure. Based on the embodiments in the present disclosure, all other embodiments acquired by a person of ordinary skill in the art based on the present disclosure shall fall within the protection scope of the present disclosure.

Multiple types of metal wires are present in the peripheral region of the display substrate, and for preventing the metal wires from reflecting light, a shielding layer or a color resistance layer is generally required for shielding, such that the reflection of the metal wires is reduced. However, for exposing an alignment mark, an opening hole is required to be formed in the shielding layer or the color resistance layer. In subsequent attachment of a cover plate, the shielding layer or the color resistance layer is likely to scratch a packaging layer at the opening hole, which affects the display effect of the display panel.

The first aspect of the present disclosure provides a display panel, as shown in FIG. 1 to FIG. 5. The display panel is provided with an display region 10 and a peripheral region 20 disposed around the display region 10. The display panel includes a display substrate and at least one alignment mark 115. The display substrate includes a base substrate 100, and a first electrode layer 106, a pixel definition layer 107, a light-emitting unit 108, and a second electrode layer 109 sequentially disposed at a side of the base substrate 100. The pixel definition layer 107 includes an opening region 1071 and a non-opening region 1072 disposed around the opening region 1071, and the light-emitting unit 108 is disposed within the opening region 1071; and the alignment mark 115 is disposed in the peripheral region 20.

The display substrate further includes a first packaging layer 110, a light-shielding layer 112, and a second packaging layer 113. The first packaging layer 110 covers the display region 10 and the peripheral region 20, the peripheral region 20 is provided with the light-shielding layer 112 at a side, distal to the base substrate 100, of the first packaging layer 110, the second packaging layer 113 is provided at a side, distal to the base substrate 100, of the light-shielding layer 112, and the second packaging layer 113 covers the display region 10 and the peripheral region 20. The light-shielding layer 112 is provided with an opening hole 1123, and a distance between a medial edge 1123a of the opening hole 1123 and a first end 112a of the light-shielding layer 112 is greater than a distance between a lateral edge 1123b of the opening hole 1123 and a second end 112b of the light-shielding layer 112. The first end 112a is an end, close to the display region 10, of the light-shielding layer 112, and the second end 112b is an end, distal to the display region 10, of the light-shielding layer 112. The medial edge 1123a of the opening hole 1123 is an edge close to the display region 10, and the lateral edge 1123b is an edge distal to the display region 10.

In the embodiments, the alignment mark 115 is made of metal, such that the metal is used as the alignment mark 115 due to the reflective property thereof. The alignment mark 115 is provided separately, which facilitates flexible selection of a position at which the alignment mark 115 is disposed. The alignment mark is disposed distal to the display region 10 and distal to a wiring region of the peripheral region 20, such that the probability of affecting the display effect is reduced in the case that the alignment mark 115 and the above opening hole 1123 cause packaging failure. As the distance between the medial edge 1123a of the opening hole 1123 and the first end 112a of the light-shielding layer 112 is greater than the distance between the lateral edge 1123b of the opening hole 1123 and the second end 112b of the light-shielding layer 112, the alignment mark 115 is distal to the display region 10 of the display panel, such that the opening hole 1123 of the light-shielding layer 112 is distal to the display region 10 as well. In the case that the opening hole 1123 or the alignment mark 115 pierces the first packaging layer 110 and/or the second packaging layer 113, a path of moisture penetrating into the display region 10 along a crack of the first packaging layer 110 or the second packaging layer 113 is extended as the opening hole 1123 is distal to the display region 10, such that the probability of affecting the display effect of the display region 10 is reduced.

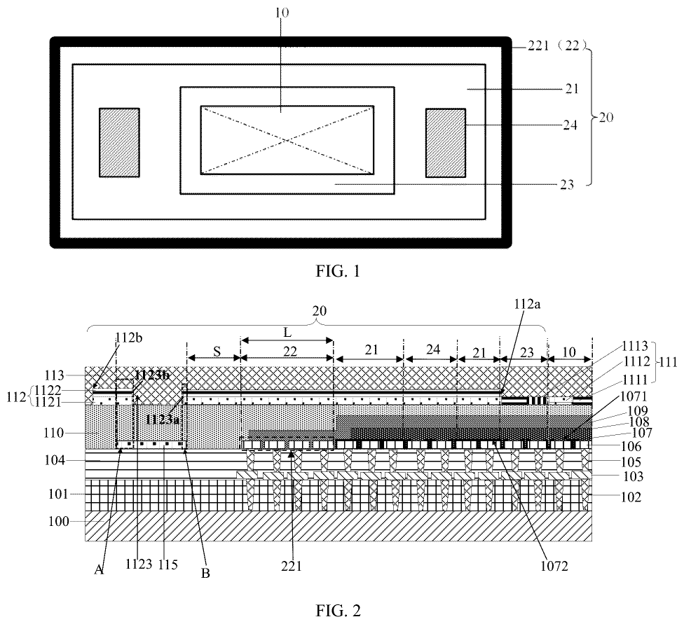

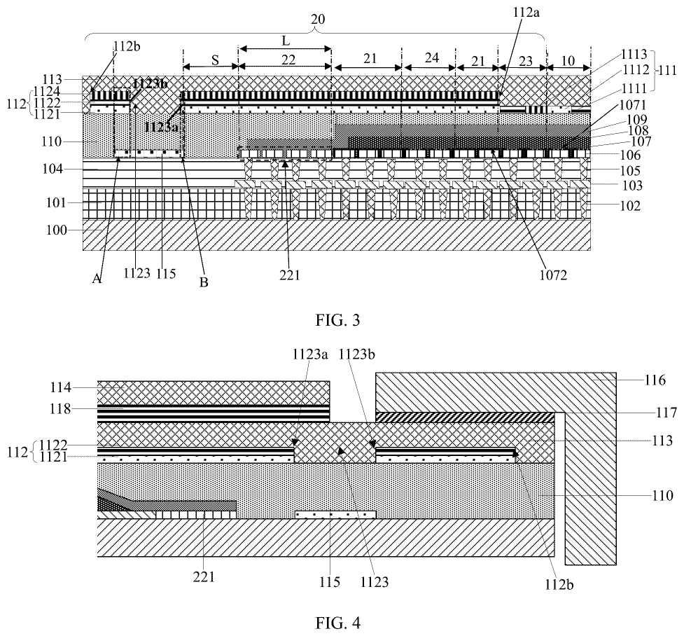

In some embodiments, as shown in FIG. 2 and FIG. 3, an orthographic projection of the opening hole 1123 on the base substrate 100 falls within an orthographic projection of the alignment mark 115 on the base substrate 100.

In the embodiments, the orthographic projection of the opening hole 1123 on the base substrate 100 is located within the range of the orthographic projection of the alignment mark 115 on the base substrate 100, i.e., an overlapping region is present between an orthographic projection of the light-shielding layer 112 near the opening hole 1123 on the base substrate 100 and the orthographic projection of the alignment mark 115 on the base substrate 100. Based on this, a position on the first packaging layer 110 with concentrated stress caused by the opening hole 1123 is not the same as a position on the first packaging layer 110 with concentrated stress caused by the alignment mark 115. As such, the stress concentration in a local region of the first packaging layer 110 is reduced, such that the risk that the opening hole 1123 pierces the first packaging layer 110 is reduced, which further reduces the probability of affecting the display effect of the display panel.

In some embodiments, as shown in FIG. 2 and FIG. 3, the peripheral region 20 of the display panel is sequentially provided with a shift pixel region 23, a dummy pixel region 21, a readout region 24, a dummy pixel region 21, and a cathode ring region 22 in a direction away from the display region 10. The alignment mark 115 is spaced apart from the cathode ring 221, and a spacing distance S between the alignment mark 115 and the cathode ring 221 is greater than a width of the cathode ring 221 L.

In the embodiments, the alignment mark 115 is spaced apart from the cathode ring 221 without using the cathode ring 221 as the alignment mark 115, such that the light-shielding layer 112 directly above the cathode ring 221 is intact with no opening hole 1123. As such, a large level difference and stress concentration in the first packaging layer 110 and the second packaging layer 113 at the position is prevented, which further solves the problem of packaging failure caused by the large level difference at the position. Even in the case that the alignment mark 115 and the opening hole 1123 opposite thereto cause damage to the first packaging layer 110 and the second packaging layer 113 above, the packaging effect of the cathode ring 221 and the light-emitting unit 108 is not affected as the alignment mark is provided separately.

It should be understood that the spacing distance S between the alignment mark 115 and the cathode ring 221 refers to a spacing distance S between the alignment mark and the cathode ring in a direction parallel to a light-emergent surface of the display panel. The width of the cathode ring L refers to a width in the direction parallel to the light-emergent surface of the display panel. The spacing distance S between the alignment mark 115 and the cathode ring 221 is greater than the width of the cathode ring L, such that the alignment mark 115 is disposed at a position other than four corners of the cathode ring 221 and further distal to the cathode ring 221. As such, the packaging effect of the cathode ring 221 and the light-emitting unit 108 is not affected in the case that the first packaging layer 110 and the second packaging layer 113 above the alignment mark 115 are damaged.

Further, it can be seen from FIG. 1, FIG. 2, and FIG. 3 that the shift pixel region 23 is disposed between the dummy pixel region 21 and the display region 10, and is configured to fine-tune a position of a display screen in an optical module or in a whole machine in an assembly manner, such that a center of the display region is located at a center of the optical module or the whole machine. The readout region 24 is disposed in the dummy pixel region 21, and the displaying luminance of the display region 10 is monitored indirectly through temperature compensation to the display region 10 by utilizing the change in a current value of the readout region 24.

In some embodiments, as shown in FIG. 4 and FIG. 5, the display panel further includes a cover plate 114 disposed at a side, distal to the base substrate 100, of the second packaging layer 113 and connected to the display substrate. An orthographic projection of an end, distal to the display region 10, of the cover plate 114 on the light-shielding layer 112 falls within a range of the opening hole 1123.

In the embodiments, the orthographic projection of the end, distal to the display region 10, of the cover plate 114 on the light-shielding layer 112 is located within the range of the opening hole 1123, such that alignment and attachment of the cover plate 114 is facilitated, and a position on the second packaging layer 113 with concentrated stress caused by the cover plate 114 is different from the position on the first packaging layer 110 with concentrated stress caused by the opening hole 1123. As such, the stress concentration in a local region of the second packaging layer 113 is reduced, such that the risk that the cover plate 114 and the opening hole 1123 pierce the second packaging layer 113 is reduced, which further reduces the probability of affecting the display effect of the display panel.

Further, as shown in FIG. 4, the orthographic projection of the end, distal to the display region 10, of the cover plate 114 on the light-shielding layer 112 is located at a central position of the opening hole 1123 to facilitate alignment and inspection of the cover plate 114 patch.

It should be understood that, as shown in FIG. 2 and FIG. 3, the distance between the medial edge 1123a of the opening hole 1123 and the first end 112a of the light-shielding layer 112 is greater than the distance between the lateral edge 1123b of the opening hole 1123 and the second end 112b of the light-shielding layer 112. As such, the orthographic projection of the opening hole 1123 on the base substrate 100 is located within the range of the orthographic projection of the alignment mark 115 on the base substrate 100 while the opening hole 1124 is further distal to the cathode ring 221, such that the packaging effect of the cathode ring 221 and the light-emitting unit 108 is not affected in the case that the first packaging layer 110 and the second packaging layer 113 above the alignment mark 115 are damaged.

The cover plate 114 is a transparent cover plate 114 made of transparent glass or other materials. The cover plate 114 is bonded to the display substrate by an optical adhesive 118, and the optical adhesive 118 is an optical clear resin (OCR) or an optically clear adhesive (OCA). The display substrate specifically includes a thin film transistor (TFT) layer and a base substrate 100. The base substrate 100 is a glass base substrate, a silicon-based base substrate, or another flexible base substrate, and the TFT layer is formed on the base substrate 100. The display substrate is specifically configured to drive each pixel point in the display panel. One of the first electrode layer 106 and the second electrode layer 109 is an anode layer, and the other is a cathode layer.

In some embodiments, as shown in FIG. 4, orthographic projections of the optical adhesive 118 and the cover plate 114 on the base substrate 100 fully cover an orthographic projection of the cathode ring 221 on the base substrate 100. Moreover, the former orthographic projections have a larger area than the latter orthographic projection. As such, the packaging effect of the material in the cathode ring region is enhanced.

It should be understood that the first electrode layer 106, the light-emitting unit 108, and the second electrode layer 109 form a light-emitting device. The pixel definition layer 107 is configured to partition a plurality of light-emitting devices, i.e., the pixel definition layer 107 is configured to define a plurality of sub-pixel regions each provided with a light-emitting device. The light-emitting device is an organic electroluminescence display (OLED), or a quantum dot light-emitting device, or another self-light-emitting device, i.e., the display panel may be an OLED display panel. In addition, the display panel may be an LED or LCD display panel, which is not limited herein.

The display substrate further includes a first packaging layer 110 and a second packaging layer 113, which are disposed at a side, distal to the base substrate 100, of the light-emitting device, for preventing moisture, oxygen, and the like in the air from corroding the light-emitting device. In some embodiments, as shown in FIG. 2 and FIG. 3, for better preventing moisture and oxygen in the air from corroding the light-emitting device, a cathode of the light-emitting device directly contacts the first packaging layer 110, i.e., the first electrode layer 106 is an anode and the second electrode layer 109 is a cathode.

In some embodiments, reflective electrodes 103 are further included between the first electrode layer 106 and the base substrate 100. In each display cell, the reflective electrode 103 is connected to a drain electrode (not shown) via a first conductive pillar 102. In the cathode ring region 22, the reflective electrode 103 is connected to a power supply electrode (not shown) via the first conductive pillar 102.

In exemplary embodiments, the reflective electrode 103 of each display cell is configured to form a microcavity structure with a subsequently formed cathode. By utilizing the strong reflection effect of the reflective electrodes 103, the light directly emitted from the light-emitting unit 108 interferes with the light reflected by the reflective electrodes 103, such that the color gamut of the emitted light is increased and the displaying brightness of the emitted light is enhanced. The reflective electrodes 103 are formed behind the first insulating layer 101 and are isolated from the first electrode layer 106 by the second insulating layer 104. The first conductive pillars 102 are filled in via holes in the first insulating layer 101.

A plurality of via holes are formed in the second insulating layer 104, and second conductive pillars 105 are filled in the via holes of the second insulating layer 104. Moreover, the second conductive pillars 105 are configured to connect to the reflective electrodes 103 of the display cells where the second conductive pillars are positioned, to connect to the reflective electrodes 103 of dummy pixels, and to connect to the reflective electrodes 103 of the cathode ring 221, respectively. In other embodiments, positions of the anode and cathode are interchanged. In some embodiments, for preventing from affecting the display effect, both the first electrode layer 106 and the second electrode layer 109 are transparent.

In some embodiments, the alignment mark 115 is disposed on the same layer as the first electrode layer 106 or the second electrode layer 109.

In the embodiments, the alignment mark 115 is disposed on the same layer as the first electrode layer 106 or the second electrode layer 109, i.e., made of the same metal as the first electrode layer 106 or the second electrode layer 109. As such, no additional processes are required, which simplifies the manufacturing process of the display panel and reduces the cost. As shown in FIG. 2 and FIG. 3, the alignment mark 115 is disposed on the same layer as the first electrode layer 106.

In some embodiments, as shown in FIG. 2 and FIG. 3, a first overlapping region A and a second overlapping region B are present between the orthographic projection of the light-shielding layer 112 on the base substrate 100 and the orthographic projection of the alignment mark 115 on the base substrate 100. The first overlapping region A is disposed at a side, distal to the display region 10, of the opening hole 1123, and the second overlapping region B is disposed at a side, close to the display region 10, of the opening hole 1123. Moreover, a width of the first overlapping region A is greater than a width of the second overlapping region B.

In the embodiments, the width of the first overlapping region A and the width of the second overlapping region B refer to widths in the direction parallel to the light-emergent surface of the display panel. The width of the first overlapping region A is greater than the width of the second overlapping region B, such that the opening hole 1123 is disposed further distal to the cathode ring 221 on the basis that the alignment mark 115 is distal to the cathode ring 221. As such, the visual effect of the screen is prevented from being affected by the fact that the opening hole 1123 region is close to the display region 10 and reflects light. Besides, the risk of packaging failure of the cathode ring 221 and the light-emitting unit 108 caused by damage to the first packaging layer 110 and the second packaging layer 113 above the alignment mark 115 is reduced.

In some embodiments, as shown in FIG. 2 and FIG. 3, the width of the second overlapping region B is smaller than the spacing distance S between the alignment mark 115 and the cathode ring 221.

In the embodiments, in the case that the position of the opening hole 1123 is fixed, a smaller width of the second overlapping region B means a larger width of the first overlapping region A. As the width of the second overlapping region B is smaller than the spacing distance S between the alignment mark 115 and the cathode ring 221, the alignment mark 115 is further distal to the display region 10, such that the visual effect of the screen is effectively prevented from being affected by the fact that the opening hole 1123 is close to the display region 10 and reflects light.

In some embodiments, as shown in FIG. 7 to FIG. 11, a longitudinal section of the opening hole 1123 has a stepped structure.

In the embodiments, the longitudinal section of the opening hole 1123 refers to a section in a direction perpendicular to the light-emergent surface of the display panel. The section has a stepped structure, for example, a one-layer stepped structure as shown in FIG. 7 to FIG. 9, or a two-layer stepped structure as shown in FIG. 10 and FIG. 11.

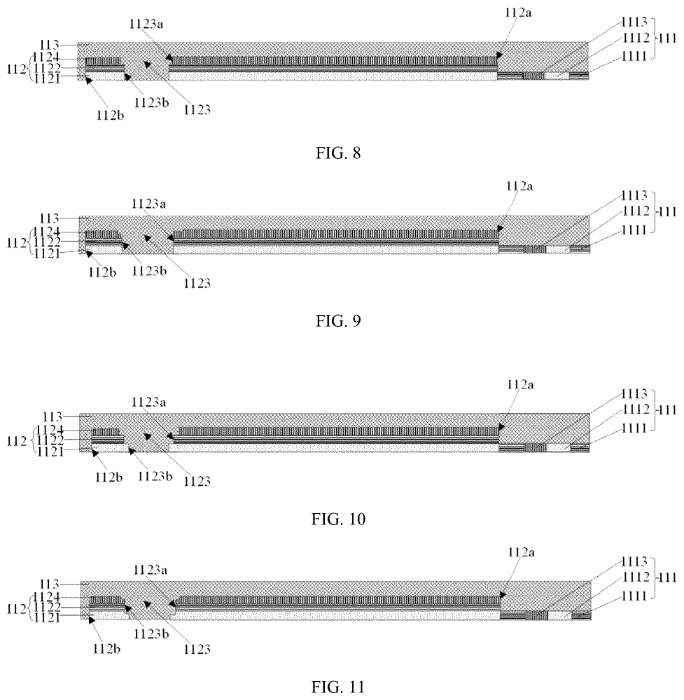

Further, for a scenario in which the longitudinal section of the opening hole 1123 has a one-layer stepped structure, as shown in FIGS. 8 and 9, a height of an upper-layer step is less than that of a lower-layer step. The upper-layer step refers to a step formed on the light-shielding layer 112, and the lower-layer step refers to a step formed between the light-shielding layer and the first packaging layer 110. As such, a gentle transition is achieved between the second packaging layer 113 and the step, a level difference of the opening hole 1123 is reduced, and the risk of piercing the second packaging layer 113 is reduced. FIG. 8 is different from FIG. 9 in that the steps are formed in different ways. In FIG. 8, the step is formed by controlling the formation of a boundary of an uppermost light-shielding layer 112, while in FIG. 9, the step is formed by depositing an uppermost light-shielding layer followed by further etching the light-shielding layer 112.

Still further, for a scenario in which the longitudinal section of the opening hole 1123 has a two-layer stepped structure, as shown in FIG. 11, heights of two layers of steps close to the first packaging layer 110 and close to the second packaging layer 113 are smaller than a height of the step between of the two layers of steps. As such, a gentle transition is achieved between the first packaging layer 110 and the step close to the first packaging layer and between the second packaging layer 113 and the step close to the second packaging layer, a level difference between every two of the foregoing is reduced, and the risk of piercing the first packaging layer 110 and the second packaging layer 113 is further reduced. Alternatively, as shown in FIG. 10, the longitudinal section with the opening hole 1123 has a two-layer stepped structure, with heights of the layers being equal.

It should be understood that the embodiments of the present disclosure are only illustrated with the light-shielding layer 112 including three layers, and the stepped structure as shown in FIG. 7 to FIG. 11 may also be formed in the case that the light-shielding layer 112 includes two layers.

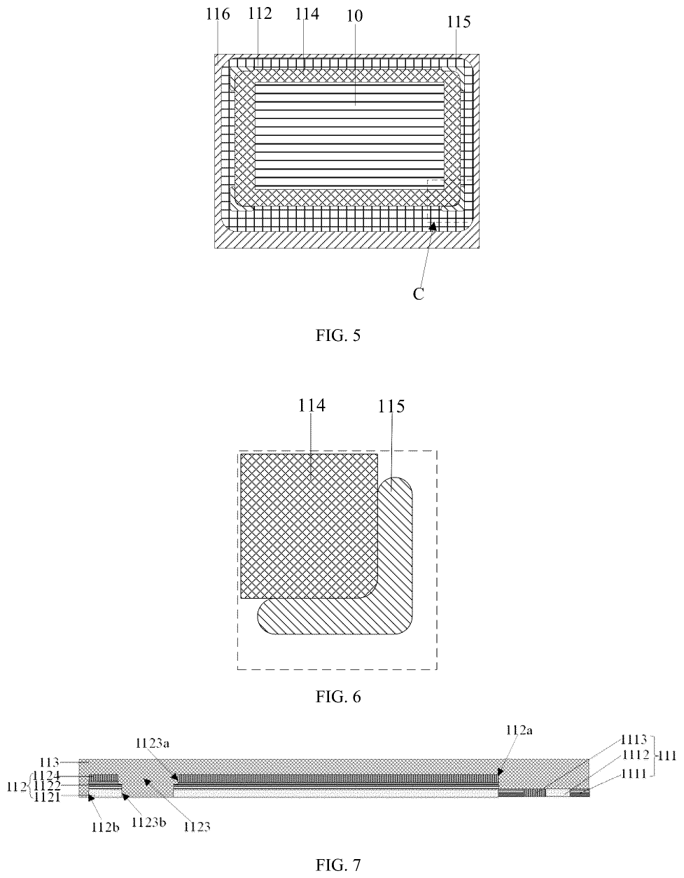

In some embodiments, as shown in FIG. 5 and FIG. 6, a section of the alignment mark 115 in a direction parallel to a major plane of the base substrate 100 is L-shaped or T-shaped or cross-shaped.

In the embodiments, the section of the alignment mark 115 in the direction parallel to the major plane of the base substrate 100 means a section in the direction parallel to the light-emergent surface of the display panel. The cross-section of the alignment mark 115 is L-shaped or T-shaped or cross-shaped, which facilitates alignment by using a cross point that is L-shaped or T-shaped or cross-shaped.

Further, the L-shaped or T-shaped or cross-shaped structure may be an integrated structure, such that the design process is simplified.

In some embodiments, a cross-section of the opening hole 1123 has the same shape as the cross-section of the alignment mark 115. The cross-section of the opening hole 1123 refers to a section in the direction parallel to the major plane of the base substrate 100. By providing the cross-section of the opening hole 1123 with the same shape as the cross-section of the alignment mark 115, the alignment mark 115 is ensured to reflect light effectively under illumination, which facilitates an accurate alignment and inspection of the cover plate.

In some embodiments, as shown in FIG. 5 and FIG. 6, vertex corners and/or edge corners of the alignment mark 115 contacting the first packaging layer 110 are rounded corners.

In the embodiments, the alignment mark 115 is L-shaped, for example, and six vertex corners and six edge corners of the alignment mark 115 contact the first packaging layer 110. The six vertex corners and the six edge corners are rounded off, such that each of the six vertex corners and the six edge corners has an arc surface, which reduces the risk of stress concentration on the first packaging layer 110 caused by the edge of the alignment mark 115, and further solves the problem that the alignment mark 115 easily pierces the packaging layer and causes packaging failure.

In some embodiments, as shown in FIG. 6, the alignment mark 115 is L-shaped, and a curvature of a medial rounded corner is greater than a curvature of a lateral rounded corner of the alignment mark 115.

In the embodiments, the medial rounded corner of the alignment mark 115 refers to a rounded corner close to the display region 10, and the lateral rounded corner refers to a rounded corner distal to the display region 10. The curvature of the medial rounded corner is larger, such that the alignment mark 115 is as distal to the cathode ring 221 as possible, i.e., the spacing distance S between the alignment mark 115 and the cathode ring 221 is increased. As such, the distance between the opening hole 1123 and the cathode ring 221 is effectively increased, and the risk of packaging failure caused by moisture penetrating along the cathode ring 221 is further reduced.

In some embodiments, as shown in FIG. 5, at least two of the alignment marks 115 are provided, and every two of the alignment marks 115 adjacent to each other are symmetrically distributed relative to the center of the display panel.

In the embodiments, two or more of the alignment marks 115 are provided, and the alignment accuracy is improved by increasing the number of the alignment marks 115. By symmetrically distributing every two of the alignment marks 115 adjacent to each other relative to the center of the display panel, the variability of the position of the cover plate 114 is reduced while the number of the alignment marks 115 is minimized, such that the alignment accuracy between the cover plate 114 and the display substrate is improved. In the case that the display panel is rectangular, for example, symmetrically distributing every two of the alignment marks 115 adjacent to each other relative to the center of the display panel means that the alignment marks 115 may be disposed at three of vertices of the rectangle, or at middle points of three of sides of the rectangle, but not one at the vertex and the other one or two at the middle point(s).

In some embodiments, as shown in FIG. 5, the display panel is rectangular, diamond-shaped, or square, and at least two of the alignment marks 115 are provided opposite respectively to positions of the vertex corners of the display panel. Alternatively, the display panel is circular, at least two of the alignment marks 115 are provided, and every two of the alignment marks 115 adjacent to each other are symmetrically distributed relative to the center of the display panel.

In the embodiments, in the case that the display panel is rectangular, diamond-shaped, or square, the alignment marks 115 are disposed at positions in the peripheral region 20 and opposite to positions of the vertex corners of the display panel. More disposal space is available in the case that the alignment marks are disposed at positions opposite to the positions of the vertex corners of the display panel. Moreover, the variability of the position of the cover plate 114 is reduced, such that the alignment accuracy of the cover plate 114 is improved.

In the case that the display panel is circular, every two of the alignment marks 115 adjacent to each other are symmetrically distributed relative to the center of the display panel, such that the alignment marks 115 are disposed on an extended line passing through the center of the circle. It should be understood that a diameter and a position of a center of a circle uniquely determine a circle. Therefore, in the case that every two of the alignment marks 115 adjacent to each other are symmetrically distributed relative to the center of the display panel, i.e., symmetrically distributed relative to the center of the circle, the position of the cover plate 114 is uniquely determined, which improves the alignment accuracy.

Further, as shown in FIG. 5, four of the alignment marks 115 are provided opposite respectively to positions of four vertex corners of the display panel. By setting the number of the alignment marks 115 to four, the alignment accuracy of the cover plate 114 is further improved.

Further, as shown in FIG. 5 and FIG. 6, edge corners and vertex corners of the light-shielding layer 112 at sides, close to the base substrate 100 and/or distal to the base substrate 100, of the opening hole 1123 are rounded corners.

In the embodiments, the sides close to the base substrate 100 and/or distal to the base substrate 100 respectively refer to a side contacting the first packaging layer 110 and a side contacting the second packaging layer 113. The edge corners and vertex corners at the two sides at the position of the opening hole 1123 of the light-shielding layer 112 are rounded off, such that sharp corners and stress concentration are prevented from occurring in the first packaging layer 110 and the second packaging layer 113 at the position, which further solves the problem of packaging failure caused by the edge of the opening hole 1123 of the light-shielding layer 112 piercing the first packaging layer 110 and the second packaging layer 113.

In some embodiments, as shown in FIG. 2, the light-shielding layer 112 includes a first peripheral color resistance layer 1121 and a second peripheral color resistance layer 1122 sequentially disposed at a side, distal to the base substrate 100, of the first packaging layer 110. The first peripheral color resistance layer 1121 and the second peripheral color resistance layer 1122 are each one of a red color resistance layer, a green color resistance layer, and a blue color resistance layer. The color resistance layer is also referred to as a filter unit.

In the embodiments, the light-shielding layer 112 is configured as two peripheral color resistance layers, such that the proportion of the reflected light from the peripheral metal wires exiting from the light-emergent surface of the display panel is reduced, which ensures the display uniformity of the peripheral region 20. The first peripheral color resistance layer 1121 and the second peripheral color resistance layer 1122 are each one of a red filter unit, a green filter unit, and a blue filter unit. For example, the first peripheral color resistance layer 1121 is the blue filter unit, and the second peripheral color resistance layer 1122 is the red filter unit. Alternatively, the first peripheral color resistance layer 1121 is the blue filter unit, and the second peripheral color resistance layer 1122 is the green filter unit. Alternatively, the first peripheral color resistance layer 1121 is the red filter unit, and the second peripheral color resistance layer 1122 is the blue filter unit, which are not limited herein. Specifically, the color of the filter unit for use as the first peripheral color resistance layer 1121 or the second peripheral color resistance layer 1122 is determined based on the manufacturing process.

Alternatively, the first peripheral color resistance layer 1121 is the blue filter unit, and the second peripheral color resistance layer 1122 is the red filter unit. The blue filter unit has high adhesiveness, such that the possibility of a color film layer 111 peeling off from the cathode is reduced by forming the blue filter unit first. As the red filter unit has small adhesiveness but good fluidity, the number of bubbles on a surface at a side, distal to the cathode, of each of the blue filter unit and the red filter unit is reduced in the process of forming the red filter unit, such that the film thickness uniformity of the blue filter unit and the red filter unit is improved.

In other embodiments, as shown in FIG. 3, the light-shielding layer 112 further includes a third peripheral color resistance layer 1124 disposed at a side, distal to the base substrate 100, of the second peripheral color resistance layer 1122. The first peripheral color resistance layer 1121, the second peripheral color resistance layer 1122, and the third peripheral color resistance layer 1124 are each one of the red color resistance layer, the green color resistance layer, and the blue color resistance layer.

In the embodiments, the light-shielding layer 112 further includes the third peripheral color resistance layer 1124, i.e., the light-shielding layer 112 is composed of three layers. Compared with the two-layer light-shielding layer 112, the three-layer light-shielding layer 112 has a better shielding effect and further alleviates light reflection in the peripheral region 20, such that the display uniformity of the peripheral region 20 is improved.

In still other embodiments, the light-shielding layer 112 is a black coating. The light-shielding layer 112 is configured as black, achieving a shielding effect without overlaying multiple layers. As such, light reflection in the peripheral region 20 is alleviated, and a reduction in the thickness of the display panel is facilitated.

In some embodiments, as shown in FIG. 2 and FIG. 3, the display region 10 is provided with a first display region color resistance layer 1111, a second display region color resistance layer 1112, and a third display region color resistance layer 1113 arranged in an array at the side, distal to the base substrate 100, of the first packaging layer 110. The first display region color resistance layer 1111, the second display region color resistance layer 1112, and the third display region color resistance layer 1113 are each one of the red color resistance layer, the green color resistance layer, and the blue color resistance layer. Each of the peripheral color resistance layers in the light-shielding layer 112 is manufactured synchronously with one of the first display region color resistance layer 1111, the second display region color resistance layer 1112, and the third display region color resistance layer 1113 in the display region 10.

In the embodiments, the display region 10 is provided with the first display region color resistance layer 1111, the second display region color resistance layer 1112, and the third display region color resistance layer 1113 arranged in the array at the side, distal to the substrate, of the packaging layer. It should be understood that a black matrix is further disposed between adjacent color resistance layers in the display region 10 to isolate the color resistance layers in the display region 10. The first display region color resistance layer 1111, the second display region color resistance layer 1112, and the third display region color resistance layer 1113 are each one of the red filter unit, the green filter unit, and the blue filter unit. The red filter unit, the green filter unit, the blue filter unit, and the black matrix absorb part of the ambient light, where the part of the light penetrating through the color film is reflected by the electrode and further absorbed by the red filter unit, the green filter unit, the blue filter unit, and the black matrix, such that the reflectance is reduced.

In the case that the light-shielding layer 112 is composed of two or three peripheral color resistance layers, each of the peripheral color resistance layers in the light-shielding layer 112 is manufactured synchronously with one of the first display region color resistance layer 1111, the second display region color resistance layer 1112, and the third display region color resistance layer 1113, i.e., in the case that only two color resistance layers are present in the peripheral region 20, the two color resistance layers are manufactured synchronously with the first two layers, the last two layers, or the first layer and the third layer, in the first color resistance layer, the second color resistance layer, and the third color resistance layer. In the case that three color resistance layers are present in the peripheral region 20, the color resistance layers in the peripheral region 20 are manufactured synchronously with manufacturing the display region 10.

Exemplarily, as shown in FIG. 3, the first display region color resistance layer 1111 is the blue filter unit, and the blue filter unit is directly evaporated onto the packaging layer. The display region 10 and the peripheral region 20 are simultaneously evaporated, except that the peripheral region 20 is not patterned after evaporation. After the first display region color resistance layer 1111 is manufactured, the mask is directly replaced in the original coating equipment, where the replacing mask is a red filter unit mask, and the red filter unit can be formed in the corresponding region of the display region 10 by evaporation. Meanwhile, the red filter unit is also formed on the blue filter unit in the peripheral region 20, i.e., the red filter unit is superposed on the surface of the blue filter unit.

Therefore, the red filter unit in the peripheral region 20, i.e., the second peripheral color resistance layer 1122 does not require an additional mask device or an additional process.

Further, the third display region color resistance layer 1113 of the embodiments is the green filter unit of the display region 10. After the blue filter unit is manufactured, the mask is directly replaced in the original coating equipment, where the replacing mask is a green filter unit mask, and the green filter unit can be formed in the corresponding region of the display region 10 by evaporation. Meanwhile, the green filter unit is also formed on the red filter unit in the peripheral region 20, i.e., the green filter unit is superposed on the surface of the red filter unit.

Therefore, in manufacturing the green filter unit in the peripheral region 20, i.e., the third peripheral color resistance layer 1124, no additional mask device or additional process is required.

It should be understood that after the color film layer 111 and the light-shielding layer 112 of the display region 10 are manufactured, the second packaging layer 113 is formed at a side, distal to the base substrate 100, of the color film layer and the light-shielding layer. The second packaging layer 113 covers the first display region color resistance layer 1111, the second display region color resistance layer 1112, the third display region color resistance layer 1113, and the light-shielding layer 112.

In some embodiments, as shown in FIG. 4, the display panel further includes a rubber frame 116, and a surface at a side, distal to the base substrate 100, of the rubber frame 116 is higher than a surface at a side, distal to the base substrate 100, of the cover plate 114.

In the embodiments, the rubber frame 116 is bonded to the second packaging layer 113 by a double-sided adhesive tape 117. For improving the attachment effect in attachment of the rubber frame 116, the weight needs to be applied above the rubber frame 116 for compaction. The surface at the side, distal to the base substrate 100, of the rubber frame 116 is higher, preventing the cover plate 114 from being pressed in the compacting process, such that the surface of the cover plate 114 is prevented from being pressed to pierce the first packaging layer 110 and the second packaging layer 113, such that the packaging reliability of the display panel is improved.

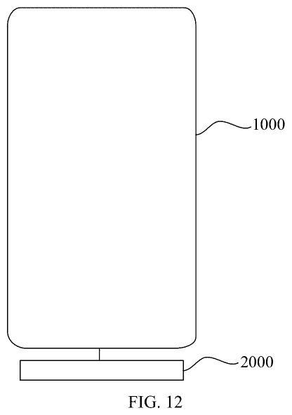

A second aspect of the present disclosure provides a display device, as shown in FIG. 12. The display device includes a display panel 1000 and a power supply assembly 2000, where the power supply assembly 2000 is configured to supply power to the display panel 1000. The display panel 1000 is the display panel as defined in the above embodiments, which includes at least one alignment mark 115 that is provided separately. The distance between the medial edge 1123a of the opening hole 1123 and the first end 112a of the light-shielding layer 112 is greater than the distance between the lateral edge 1123b of the opening hole 1123 and the second end 112b of the light-shielding layer 112. As such, the alignment mark 115 is distal to the display region 10 of the display panel, such that the opening hole 1123 of the light-shielding layer 112 is distal to the display region 10 as well. In the case that the opening hole 1123 or the alignment mark 115 pierces the first packaging layer 110 and/or the second packaging layer 113, a path of moisture penetrating into the display region along a crack of the first packaging layer 110 or the second packaging layer 113 is extended as the opening hole 1123 is distal to the display region 10, such that the probability of affecting the display effect of the display region 10 is effectively reduced.

It should be understood that relational terms used herein, such as first and second, may be used solely to distinguish one entity or operation from another entity or operation without necessarily requiring or implying any such actual relationship or order between such entities or operations. Moreover, the terms “includes”, “including”, or any other variation thereof, are intended to encompass a non-exclusive inclusion, such that a process, method, item, or device that includes a list of elements does not include only those elements but also include other elements not expressly listed or elements inherent to such process, method, item, or device. Without further limitation, an element defined by the phrase “including a . . . ” does not exclude the presence of additional identical elements in the process, method, item, or device that includes the element.

The embodiments herein are described in a related manner, and the same and similar parts among the embodiments may be referred to each other, and each embodiment focuses on differences from the other embodiments.

The foregoing shows only alternative embodiments of the present disclosure and is not intended to limit the protection scope of the present disclosure. Any modifications, equivalent substitutions, improvements, and the like, made within the spirit and principle of the present disclosure, should be included in the protection scope of the present disclosure.

1. A display panel provided with a display region and a peripheral region disposed around the display region, the display panel comprising:
a display substrate, comprising a base substrate, and a first electrode layer, a pixel definition layer, a light-emitting unit, and a second electrode layer sequentially disposed at a side of the base substrate, wherein the pixel definition layer is provided with an opening region and a non-opening region surrounding the opening region, and the light-emitting unit is disposed in the opening region; and
at least one alignment mark disposed in the peripheral region, wherein
the display substrate further comprises: a first packaging layer, a light-shielding layer, and a second packaging layer sequentially disposed at a side, distal to the base substrate, of the second electrode layer, wherein the first packaging layer covers the display region and the peripheral region, the light-shielding layer is disposed in the peripheral region, and the second packaging layer covers the display region and the peripheral region; the light-shielding layer is provided with an opening hole, and the opening hole is disposed opposite to the alignment mark; and
a distance between a medial edge of the opening hole and a first end of the light-shielding layer is greater than a distance between a lateral edge of the opening hole and a second end of the light-shielding layer, wherein the first end is an end, close to the display region, of the light-shielding layer, and the second end is an end, distal to the display region, of the light-shielding layer.

2. The display panel according to claim 1, wherein an orthographic projection of the opening hole on the base substrate falls within an orthographic projection of the alignment mark on the base substrate.

3. The display panel according to claim 1, wherein the display substrate further comprises a cathode ring disposed in the peripheral region, the alignment mark is spaced apart from the cathode ring, and a spacing distance between the alignment mark and the cathode ring is greater than a width of the cathode ring.

4. The display panel according to claim 1, wherein the display panel further comprises a cover plate disposed at a side, distal to the base substrate, of the second packaging layer and connected to the display substrate; and
an orthographic projection of an end, distal to the display region, of the cover plate on the light-shielding layer falls within the opening hole.

5. The display panel according to claim 1, wherein the alignment mark is disposed on a same layer as the first electrode layer or the second electrode layer.

6. The display panel according to claim 3, wherein a first overlapping region and a second overlapping region are present between an orthographic projection of the light-shielding layer on the base substrate and an orthographic projection of the alignment mark on the base substrate, the first overlapping region is disposed at a side, distal to the display region, of the opening hole, the second overlapping region is disposed at a side, close to the display region, of the opening hole, and a width of the first overlapping region is greater than a width of the second overlapping region.

7. The display panel according to claim 6, wherein the width of the second overlapping region is smaller than the spacing distance between the alignment mark and the cathode ring disposed in the peripheral region.

8. The display panel according to claim 1, wherein a longitudinal section of the opening hole has a stepped structure.

9. The display panel according to claim 1, wherein a section of the alignment mark in a direction parallel to a major plane of the base substrate is L-shaped or T-shaped or cross-shaped.

10. The display panel according to claim 9, wherein vertex corners and/or edge corners of the alignment mark contacting the first packaging layer are rounded corners.

11. The display panel according to claim 10, wherein the alignment mark is L-shaped, and a curvature of a medial rounded corner is greater than a curvature of a lateral rounded corner of the alignment mark.

12. The display panel according to claim 1, wherein at least two of the alignment marks are provided, and every two of the alignment marks adjacent to each other are symmetrically distributed relative to a center of the display panel.

13. The display panel according to claim 12, wherein the display panel is rectangular, diamond-shaped, or square, and the alignment marks are opposite respectively to positions of vertex corners of the display panel; or the display panel is circular.

14. The display panel according to claim 12, wherein the display panel is rectangular, diamond-shaped, or square, and four of the alignment marks are provided opposite respectively to positions of four vertex corners of the display panel.

15. The display panel according to claim 1, wherein edge corners and vertex corners of the light-shielding layer at sides, close to the base substrate and/or distal to the base substrate, of the opening hole are rounded corners.

16. The display panel according to claim 1, wherein the light-shielding layer comprises a first peripheral color resistance layer and a second peripheral color resistance layer sequentially disposed at a side, distal to the base substrate, of the first packaging layer, wherein the first peripheral color resistance layer and the second peripheral color resistance layer are each one of a red color resistance layer, a green color resistance layer, and a blue color resistance layer.

17. The display panel according to claim 16, wherein the light-shielding layer further comprises a third peripheral color resistance layer disposed at a side, distal to the base substrate, of the second peripheral color resistance layer, wherein the first peripheral color resistance layer, the second peripheral color resistance layer, and the third peripheral color resistance layer are each one of the red color resistance layer, the green color resistance layer, and the blue color resistance layer.

18. The display panel according to claim 1, wherein the light-shielding layer is a black coating.

19. The display panel according to claim 1, wherein the display panel further comprises a rubber frame, and a surface at a side, distal to the base substrate, of the rubber frame is higher than a surface at a side, distal to the base substrate, of the cover plate.

20. A display device, comprising a power supply assembly and a display panel, wherein the power supply assembly is configured to supply power to the display panel, the display panel is provided with a display region and a peripheral region disposed around the display region, and the display panel comprises:
a display substrate, comprising a base substrate, and a first electrode layer, a pixel definition layer, a light-emitting unit, and a second electrode layer sequentially disposed at a side of the base substrate, wherein the pixel definition layer is provided with an opening region and a non-opening region surrounding the opening region, and the light-emitting unit is disposed in the opening region; and
at least one alignment mark disposed in the peripheral region, wherein
the display substrate further comprises: a first packaging layer, a light-shielding layer, and a second packaging layer sequentially disposed at a side, distal to the base substrate, of the second electrode layer, wherein the first packaging layer covers the display region and the peripheral region, the light-shielding layer is disposed in the peripheral region, and the second packaging layer covers the display region and the peripheral region; the light-shielding layer is provided with an opening hole, and the opening hole is disposed opposite to the alignment mark; and
a distance between a medial edge of the opening hole and a first end of the light-shielding layer is greater than a distance between a lateral edge of the opening hole and a second end of the light-shielding layer, wherein the first end is an end, close to the display region, of the light-shielding layer, and the second end is an end, distal to the display region, of the light-shielding layer.
